(19) United States
(12) Patent Application Publication
(10) Pub. No.: US 2018/0013098 A1
(43) Pub. Date: Jan. 11, 2018

(54) Organic Light-Emitting Display Panel and Device

(71) Applicant: SHANGHAI TIANMA AM-OLED CO., LTD., Shanghai (CN)

(72) Inventors: Xiangcheng WANG, Shanghai (CN); Jinghua NIU, Shanghai (CN); Yuji HAMADA, Shanghai (CN); Shuang CHENG, Shanghai (CN); Wei HE, Shanghai (CN); Wanming HUA, Shanghai (CN)

(21) Appl. No.: 15/697,384

(22) Filed: Sep. 6, 2017

(30) Foreign Application Priority Data
Jan. 16, 2017 (CN) 201710028456.2

(51) Int. Cl. H01L 51/52; H01L 51/50

(52) U.S. Cl. CPC H01L 51/5265; H01L 51/5096; H01L 51/5016; H01L 51/5056; H01L 51/5076; H01L 51/5221; H01L 51/5206; H01L 51/5004; H01L 51/5092; H01L 51/5088; H01L 2251/301; H01L 2251/5353; H01L 2251/552; H01L 2251/558

(57) ABSTRACT

An organic light-emitting display panel and an organic light-emitting display device are disclosed, wherein the organic light-emitting display panel includes: a substrate, a cathode, a first auxiliary functional structure, a light-emitting structure and an anode that are successively laminated; wherein, the material of both the anode and the cathode is silver or a silver-containing metallic material, and a micro-cavity structure is formed between the cathode and the anode; the first auxiliary functional structure includes at least one of an electron injection layer, an electron transport layer and a hole blocking layer, and the first auxiliary functional structure is multiplexed as a micro-cavity length adjusting structure.

### CROSS-REFERENCE TO RELATED APPLICATIONS

This application claims priority to Chinese Patent Application No. CN201710028456.2, filed on Jan. 16, 2017 and entitled “ORGANIC LIGHT-EMITTING DISPLAY PANEL AND DEVICE”, the disclosure of which is incorporated herein by reference in its entirety.

### TECHNICAL FIELD

Embodiments of the present disclosure relate to organic light-emitting display technologies, and in particular, to an organic light-emitting display panel and an organic light-emitting display device.

### BACKGROUND

Due to technical advantages of display without a backlight source, such as high contrast, small thickness, large visual angle and fast reaction speed, etc., Organic Light-Emitting Display (OLED) has become one of the important development trends of the display industries.

In the structure of traditional organic light-emitting display panels, the luminescent characteristics may be adjusted by introducing an optical micro-resonant cavity (micro-cavity structure, for short). The micro-cavity structure is formed of multilayer films between the two electrodes of the organic light-emitting display panel, wherein the sum of the thickness of each of film layers is the cavity length of the micro-cavity structure, and hence the cavity length of the micro-cavity may be tuned by adjusting the thickness of each of the film layers in the micro-cavity, so that the organic light-emitting display device can meet various optical performance indexes. In the existing organic light-emitting display panels, the hole transport layer is multiplexed as a micro-cavity length adjusting structure. The high light-emitting efficiency and lightness as expected may be obtained by changing the thickness of the hole transport layer. However, such a method is only applicable to upright organic light-emitting display panel, not applicable to inverted organic light-emitting display panel. In an inverted organic light-emitting display panel, the light-emitting efficiency and the lightness thereof cannot be improved by multiplexing the hole transport layer as the micro-cavity length adjusting structure, and hence the light-emitting efficiency of the existing inverted organic light-emitting display panel is very low.

### SUMMARY

The present disclosure provides an organic light-emitting display panel and an organic light-emitting display device, thereby improving the light-emitting efficiency and the lightness of the organic light-emitting display panel.

In a first aspect, embodiments of the present disclosure provide an organic light-emitting display panel, comprising

a substrate, a cathode, a first auxiliary functional structure, a light-emitting structure and an anode that are successively laminated;

wherein, the anode and the cathode are both made of silver or a silver-containing metallic material, and a micro-cavity structure is formed between the cathode and the anode;

the first auxiliary functional structure includes at least one of an electron injection layer, an electron transport layer and a hole blocking layer, and the first auxiliary functional structure is multiplexed as a micro-cavity length adjusting structure.

In a second aspect, embodiments of the present disclosure further provide an organic light-emitting display device, which includes any organic light-emitting display panel according to the embodiments of the present disclosure.

In the embodiments of the present disclosure, the problem of low light-emitting efficiency of the existing inverted organic light-emitting display panel may be solved by multiplexing the first auxiliary functional structure located between the cathode and the light-emitting structure as a micro-cavity length adjusting structure, thereby increasing the objects of increasing the light-emitting efficiency and the lightness of inverted organic light-emitting display panels and improving the performance of inverted organic light-emitting display panels.

### BRIEF DESCRIPTION OF THE DRAWINGS

FIG. 1 is a structural representation of an organic light-emitting display panel according to one embodiment of the present disclosure;

FIG. 2 is a structural representation of another organic light-emitting display panel according to one embodiment of the present disclosure;

FIG. 3 is a structural representation of yet another organic light-emitting display panel according to one embodiment of the present disclosure;

FIG. 4 is a structural representation of yet another organic light-emitting display panel according to one embodiment of the present disclosure;

FIG. 5 is a structural representation of yet another organic light-emitting display panel according to one embodiment of the present disclosure;

FIG. 6 is a structural representation of yet another organic light-emitting display panel according to one embodiment of the present disclosure;

FIG. 7 is a structural representation of yet another organic light-emitting display panel according to one embodiment of the present disclosure; and

FIG. 8 is a structural representation of an organic light-emitting display device according to one embodiment of the present disclosure.

### DETAILED DESCRIPTION

The present disclosure will be further illustrated in detail in conjunction with the drawings and embodiments. It may be understood that, the specific embodiments described here are only set for explaining, rather than limiting, the present disclosure. Additionally, it further needs to be noted that, for convenient description, the drawings only show the parts related to the disclosure, rather than the whole structure.

Organic light-emitting display panels mainly have two types, namely upright organic light-emitting display panels and inverted organic light-emitting display panels. Among them, an upright organic light-emitting display panel includes a substrate, an anode, a light-emitting structure and a cathode that are successively laminated. The active metal in the cathode of the organic light-emitting display panel with such a structure tends to be eroded by water and oxygen, which causes a very short lifetime of the organic light-emitting display panel. An inverted organic light-emitting display panel includes a substrate, a cathode, a light-emitting structure and an anode that are successively laminated. In the inverted organic light-emitting display panel, the active metal in the cathode may be well protected from being eroded by water and oxygen; however, the light-emitting efficiency of the inverted organic light-emitting display panel is much lower than that of the upright organic light-emitting display panel, which cannot meet the requirements on organic light-emitting display panels in the market.

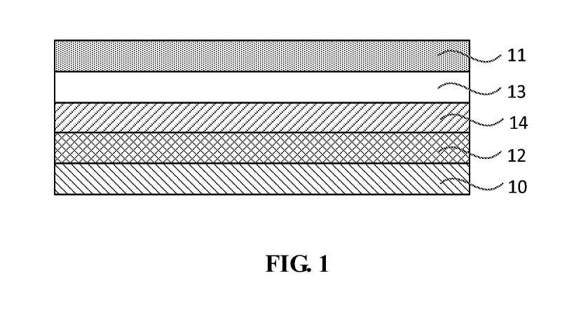

FIG. 1 is a structural representation of an organic light-emitting display panel according to one embodiment of the present disclosure. Referring to FIG. 1, the organic light-emitting display panel includes: a substrate 10, a cathode 12, a first auxiliary functional structure 14, a light-emitting structure 13 and an anode 11 that are successively laminated. The material of both the cathode 12 and the anode 11 is silver or a silver-containing metallic material, and a micro-cavity structure is formed between the cathode 12 and the anode 11; the first auxiliary functional structure 14 includes at least one of an electron injection layer, an electron transport layer and a hole blocking layer, and the first auxiliary functional structure 14 is multiplexed as a micro-cavity length adjusting structure.

With the micro-cavity structure, light can be restricted within a very small wavelength range by using the effects of reflection, total reflection, interference, diffraction or scattering, etc., of the light on the interfaces with discontinuous refractive indexes. By designing the cavity length and optimizing the thickness of each layer within the cavity, the luminescence center can be made in the vicinity of the enhanced peak of the stationary field in the cavity, and hence the coupling efficiency of the radiating doublet of the organic light-emitting display panel and the electric field in the cavity may be improved, so that the light-emitting efficiency and the lightness of the organic light-emitting display panel may be improved. Multiplexing the first auxiliary functional structure 14 as a micro-cavity length adjusting structure is essentially to locate the light-emitting structure 13 in the vicinity of the enhanced peak of the stationary field in the micro-cavity by adjusting the thickness of the first auxiliary functional structure 14. Exemplarily, the light-emitting structure 13 coincides with the peak of the standing wave in the micro-cavity or coincides with the trough of the standing wave in the micro-cavity.

The material of the light-emitting structure 13 is an organic material (host) doped with a light-emitting material (dopant). It should be understood by one skilled in the art that, the content of the organic material (host) in the light-emitting structure 13 is greater than that of the light-emitting material (dopant). Optionally, the mass percent of the light-emitting material (dopant) in the light-emitting structure 13 is 1%˜20%. The organic material (host) in the light-emitting structure 13 may only include one organic material, or alternatively it may include a plurality of organic materials. The light-emitting material (dopant) of the light-emitting structure 13 may contain a red light-emitting material, a green light-emitting material and a blue light-emitting material. In use, optionally, the light emitted by the red light-emitting material, the light emitted by the green light-emitting material and the light emitted by the blue light-emitting material are mixed to obtain white light. The red light-emitting material and the green light-emitting material may contain a phosphorescent material, and the blue light-emitting material may contain a fluorescent material. The fluorescent material may contain a thermally-activated delayed fluorescent material.

Moreover, when the organic light-emitting display panel includes a plurality of pixel regions that emit light of different colors, because the cavity length of the micro-cavity structure corresponding to the pixel region is related to the wavelength of the color of the emitted light corresponding to the pixel region, the micro-cavity structures corresponding to pixel regions that emit light of different colors are optionally set to have different cavity lengths, that is, the first auxiliary functional structure 14 corresponding to pixel regions that emit light of different colors has different thickness, so that each pixel region of the organic light-emitting display panel may have good light-emitting efficiency and lightness.

In specific arrangement, the thickness of the micro-cavity length adjusting structure (the first auxiliary functional structure 14) is determined according to the performance requirement of the organic light-emitting display panel to be manufactured, which is not limited in the present application. Optionally, the thickness of the micro-cavity length adjusting structure (the first auxiliary functional structure 14) is greater than 600 Å.

The first auxiliary functional structure 14 includes at least one of an electron injection layer, an electron transport layer and a hole blocking layer. The electron injection layer functions to lower the interfacial energy barrier between the cathode 12 and the organic material, and to improve the electron injection capacity. The electron transport layer functions to transport the electrons generated by the cathode 12 to the light-emitting structure 13, so that the holes and the electrons may be recombined to generate excitons, thereby enabling the organic light-emitting display panel emit light. The electron blocking layer functions to block the holes transported from the anode 11 from passing through the light-emitting structure 13 and further moving toward the cathode 12, so that the hole-electron recombining region in the organic display panel may be restricted in the light-emitting structure 13. In the case that the first auxiliary functional structure 14 includes an electron transport layer, optionally, only the electron transport layer is multiplexed as a micro-cavity length adjusting structure.

In the embodiments of the present disclosure, the problem of low light-emitting efficiency of the existing inverted organic light-emitting display panel may be solved by multiplexing the first auxiliary functional structure 14 located between the cathode 12 and the light-emitting structure 13 as a micro-cavity length adjusting structure, thereby attaining the objects of increasing the light-emitting efficiency and the lightness of the organic light-emitting display panel and improving the performance of the organic light-emitting display panel.

During functioning of the organic light-emitting display panel, a bias voltage is applied between the anode 11 and the cathode 12 of the organic light-emitting display panel, holes are injected from the anode 11 and migrate toward the light-emitting structure 13 via the first hole transport layer 14, electrons are injected from the cathode 12 and migrate toward the light-emitting structure 13. On the light-emitting structure 13, holes and electrons are recombined to generate excitons. The excitons are unstable, and hence energy can be released. The energy is transferred to the molecules of the organic light-emitting material in the light-emitting structure 13, so that the molecules transit from a ground state to an excited state. The excited state is very unstable, and thus the excited molecules return to the ground state from the excited state, so that a light emitting phenomenon appears due to radiative transition. Therefore, in the organic light-emitting display panel, the performance of the organic light-emitting display panel is determined by the hole-electron recombination efficiency. Moreover, the performance of the injection of holes and electrons would affect the hole-electron recombination efficiency.

Based on the above technical solution, optionally, the electron transport layer is doped with at least one of an alkali metal, an alkaline earth metal and a rare earth metal. Exemplarily, the electron transport layer is doped with at least one of lithium, cesium or ytterbium. It may be known according to Fowler-Nordheim (FN) tunneling model that, with such an arrangement, the interfacial energy barrier between the cathode 12 and the organic material (for example, the light-emitting structure 13) of the organic light-emitting display panel may be lowered, thereby improving the electron injection capacity, facilitating the adjustment of the charge balance in the organic light-emitting display panel and lowering the bias voltage required by the organic light-emitting display panel, so that the light-emitting efficiency of the organic light-emitting display panel may be improved. In specific arrangement, appropriate mass percent of the metal doped in the electron transport layer and appropriate thickness of the electron transport layer may be selected according to the performance requirement of the organic light-emitting display panel to be manufactured. Optionally, the mass percent of the metal doped in the electron transport layer is greater than or equal to 5% and is less than or equal to 50%, and the thickness of the electron transport layer is greater than 200 Å.

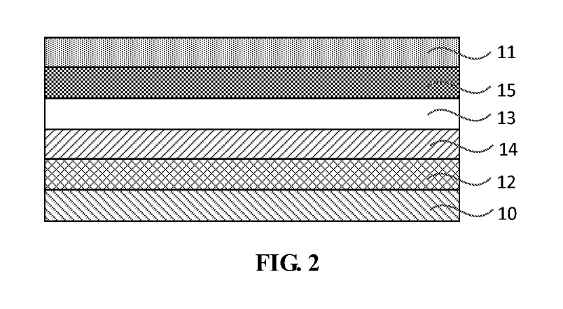

FIG. 2 is a structural representation of another organic light-emitting display panel according to one embodiment of the present disclosure. In comparison with FIG. 1, the organic light-emitting display panel in FIG. 2 further includes a second auxiliary functional structure 15; the second auxiliary functional structure 15 is located between the light-emitting structure 13 and the anode 11; and the second auxiliary functional structure 15 includes at least one of an electron blocking layer, a hole transport layer and a hole injection layer. The electron blocking layer functions to block the electrons transported from the cathode 12 from passing through the light-emitting structure 13 and further moving toward the anode 11, so that the hole-electron recombination region in the organic light-emitting display panel is restricted in the light-emitting structure 13. The hole injection layer functions to lower the interfacial energy barrier between the anode 11 and the organic material and improve the hole injection capacity. The hole transport layer functions to transport the holes generated by the anode 11 to the light-emitting structure 13, so that the holes and the electrons are recombined to generate excitons, thereby enabling the organic light-emitting display panel emit light.

The second auxiliary functional structure 15 may include a hole transport layer, and optionally, the hole transport layer is doped with a P-type semiconductor material. The material of both the anode 11 and the cathode 12 is silver or a silver-containing metallic material. It may be known according to Fowler-Nordheim (FN) tunneling model that, by setting the material of the anode 11 as silver or a silver-containing metallic material and setting the material of the hole transport layer as a conductive material doped with a P-type semiconductor material, it may help to lower the interfacial energy barrier between the anode 11 and hole transport layer, and hence improve the hole injection capacity and facilitate hole injection, facilitate adjustment of the charge balance in the organic light-emitting display panel and lower the bias voltage required by the organic light-emitting display panel, so that the light-emitting efficiency of the organic light-emitting display panel may be improved and the lifetime of the organic light-emitting display panel may be prolonged.

In the specific arrangement, appropriate mass percent of the P-type semiconductor material in hole transport layer and appropriate thickness of the hole transport layer may be selected according to the performance requirement of the organic light-emitting display panel to be manufactured. Optionally, the mass percent of the P-type semiconductor material in the hole transport layer may be greater than or equal to 1% and be less than or equal to 10%, and the thickness of the hole transport layer may be greater than or equal to 50 Å and be less than or equal to 300 Å.

The transportation of holes in the hole transport layer is essentially realized by filling the holes with electrons successively in a certain direction. Specifically, under the action of the electric field, electrons located on the highest occupied molecular orbit (HOMO) energy level in the hole transport layer are transited to the lowest unoccupied molecular orbit (LUMO) energy level of the P-type semiconductor material, and fill the holes near the anode 11, so as to form new holes that are nearer to the light-emitting structure 13. Therefore, if the lowest unoccupied molecular orbit (LUMO) energy level of the P-type semiconductor material is close to the highest occupied molecular orbit (HOMO) energy level of the hole transport layer, it will facilitate generation of holes. Optionally, the lowest unoccupied molecular orbit (LUMO) energy level of the P-type semiconductor material is less than −5 eV.

It should be noted that, in specific arrangement, in order to adjust the charge balance in the organic light-emitting display panel, it needs to be considered comprehensively, rather than independently, when determining the mass percent of the P-type semiconductor material in the hole transport layer, the thickness of the hole transport layer, the mass percent of the metal doped in the electron transport layer and the thickness of the electron transport layer.

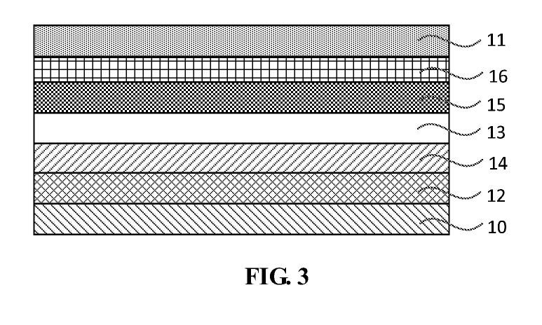

FIG. 3 is a structural representation of another organic light-emitting display panel according to one embodiment of the present disclosure. In comparison with FIG. 2, the hole transport layer in the second auxiliary functional structure 15 of the organic light-emitting display panel in FIG. 3 is not doped with a P-type semiconductor material; instead, a P-type semiconductor material layer 16 is provided between the hole transport layer and the anode 11. The material of both the anode 11 and the cathode 12 is silver or a silver-containing metallic material. Similarly, it may be known according to Fowler-Nordheim (FN) tunneling model that, by setting the material of the anode 11 as silver or a silver-containing metallic material and setting a P-type semiconductor material layer 16 between the hole transport layer and the anode 11, it may help to lower the interfacial energy barrier between the anode 11 and the organic material, improve the hole injection capacity and facilitate hole injection.

In the specific arrangement, a P-type semiconductor material layer 16 with an appropriate thickness may be manufactured according to the performance requirement of the organic light-emitting display panel to be manufactured, which is not limited in the present application.

Moreover, the lowest unoccupied molecular orbital energy level of the P-type semiconductor material is less than −5 eV.

Similarly, the electron transport layer may be doped with at least one of an alkali metal, an alkaline earth metal and a rare earth metal. In the specific arrangement, in order to adjust the charge balance in the organic light-emitting display panel, it needs to be considered comprehensively, rather than independently, when determining the thickness of the P-type semiconductor material layer, the mass percent of the metal doped in the electron transport layer and the thickness of the electron transport layer.

In the above technical solution, optionally, the material of both the anode 11 and the cathode 12 is a silver-containing metallic material. The mass percent of silver is greater than or equal to 10%. For example, the material of the anode 11 and the cathode 12 may be a silver-magnesium alloy or a silver-ytterbium alloy. In use, at least one of the anode 11 and the cathode 12 may function as an emergent light side electrode of the organic light-emitting display panel. Detailed illustration will be given below by typical examples.

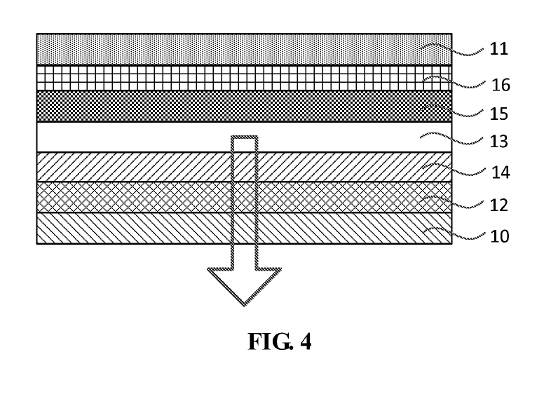

FIG. 4 is a structural representation of yet another organic light-emitting display panel according to one embodiment of the present disclosure. Referring to FIG. 4, in the organic light-emitting display panel, only the cathode 12 is taken as an emergent light side electrode, and light is emitted out via the cathode 12 and the substrate 10 after being formed in the light-emitting structure 13. Such an organic light-emitting display panel is also referred to as an inverted bottom-emission type organic light-emitting display panel. The material of both the anode 11 and the cathode 12 is silver or a silver-containing metallic material. In order to make the anode 11 have good reflection effect and make the cathode 12 have good light transmittance, the thickness of the anode 11 may be set as greater than 30 nm, and the thickness of the emergent light side electrode (the cathode 12) may be set as less than 30 nm.

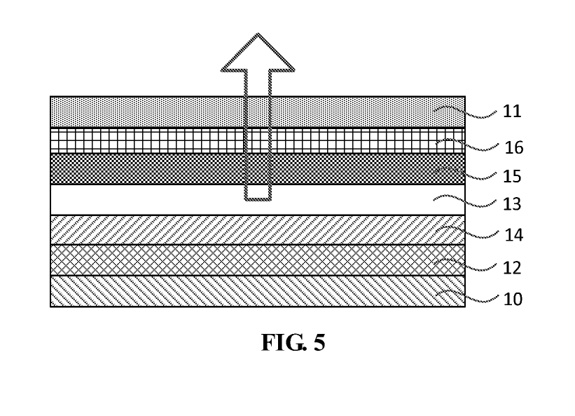

FIG. 5 is a structural representation of yet another organic light-emitting display panel according to one embodiment of the present disclosure. Referring to FIG. 5, in the organic light-emitting display panel, only the anode 11 is taken as an emergent light side electrode, and light is emitted out via the anode 11 after being formed on the light-emitting structure 13. Such an organic light-emitting display panel is also referred to as an inverted top-emission type organic light-emitting display panel. The material of both the anode 11 and the cathode 12 is silver or a silver-containing metallic material. In order to make the cathode 12 have good reflection effect and make the anode 11 have good light transmittance, the thickness of the cathode 12 may be set as greater than 30 nm, and the thickness of the emergent light side electrode (the anode 11) may be set as less than 30 nm.

TABLE 1

| | Bias Voltage | Efficiency | Lifetime |
|---|---|---|---|
| Experimental Group | 3.8 V | 105 | 102 h |
| Contrast Group 1 | 4.2 V | 105 | 100 h |
| Contrast Group 2 | 4.2 V | 100 | 50 h |

Performance parameters of different organic light-emitting display panels are given in Table 1. Each performance parameter for characterizing the performance of the organic light-emitting display panel in the table is measured under the same experimental conditions (including the same current density). The organic light-emitting display panel in Contrast Group 1 is the existing upright top-emission type organic light-emitting display panel, wherein the hole transport layer thereof is multiplexed as a micro-cavity length adjusting structure, and the electron transport layer thereof is not doped with ytterbium, the hole transport layer is not doped with a P-type semiconductor material. Contrast group 2 is an inverted top-emission type organic light-emitting display panel, wherein the hole transport layer thereof is taken as a micro-cavity length adjusting structure, and the electron transport layer thereof is doped with ytterbium, the hole transport layer is doped with a P-type semiconductor material. The organic light-emitting display panel in Experimental Group is an inverted top-emission type organic light-emitting display panel according to the present application, wherein the electron transport layer thereof is multiplexed as a micro-cavity length adjusting structure, and the electron transport layer thereof is doped with ytterbium, the hole transport layer is doped with a P-type semiconductor material.

In Table 1, “Bias Voltage” refers to a bias voltage applied by the anode 11 and the cathode 12 on the organic light-emitting display panel. “Efficiency” represents current efficiency divided by color coordinate Y (Cd/A/CIEY). “Lifetime” refers to the working time of an organic light-emitting display panel for which the luminance of the organic light-emitting display panel attenuates from initial lightness to 95% of the initial lightness.

It may be found by comparing Contrast Group 1 with Contrast Group 2. The bias voltage required by the inverted organic light-emitting display panel in Contrast Group 2 is equal to that required by the upright organic light-emitting display panel in Contrast Group 1; however, the efficiency of the inverted organic light-emitting display panel in Contrast Group 2 is a little lower than that of the upright organic light-emitting display panel in Contrast Group 1, and the lifetime of the inverted organic light-emitting display panel in Contrast Group 2 is much shorter than that of the upright organic light-emitting display panel in Contrast Group 1. Because the electron transport layer is doped with ytterbium, and the hole transport layer is doped with a P-type semiconductor material, it can facilitate the charge balance in the organic light-emitting display panel, improve the light-emitting efficiency of the organic light-emitting display panel and prolong the lifetime of the organic light-emitting display panel. On the other hand, for the organic light-emitting display panel in Contrast Group 2 in which the electron transport layer is doped with ytterbium and the hole transport layer is doped with a P-type semiconductor material, the efficiency thereof is still lower than that of the upright organic light-emitting display panel in Contrast Group 1, and the lifetime thereof is shorter than that of the upright organic light-emitting display panel in Contrast Group 1. This indicates that the light-emitting efficiency of the inverted organic light-emitting display panel cannot be improved and the lifetime of the organic light-emitting display panel cannot be prolonged by multiplexing the hole transport layer as a micro-cavity length adjusting structure.

It may be found by comparing Contrast Group 1 with Experimental Group that, for the inverted organic light-emitting display panel according to the embodiments of the present application, by multiplexing the electron transport layer as a micro-cavity length adjusting structure, the efficiency of the inverted organic light-emitting display panel in Experimental Group is equal to that of the upright organic light-emitting display panel in Contrast Group 1, the bias voltage required by the inverted organic light-emitting display panel in the Experimental Group is lower than that required by the upright organic light-emitting display panel in Contrast Group 1, and the lifetime of the inverted organic light-emitting display panel in Experimental Group is even somewhat longer than the lifetime of the upright organic light-emitting display panel in Contrast Group 1. This indicates that, by multiplexing the electron transport layer as a micro-cavity length adjusting structure, it positively helps to increase the light-emitting efficiency and the lightness of inverted organic light-emitting display panels and improve the performance of inverted organic light-emitting display panels.

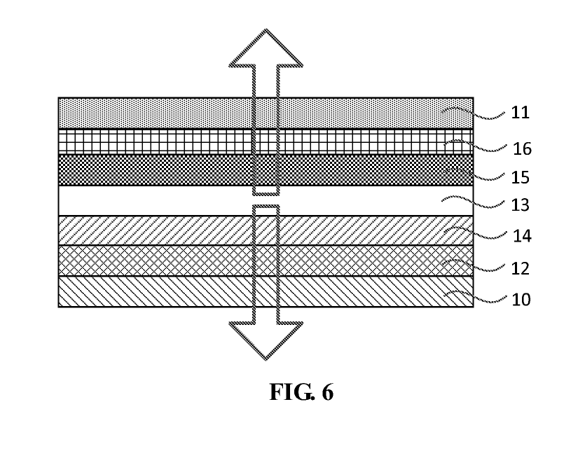

FIG. 6 is a structural representation of yet another organic light-emitting display panel according to one embodiment of the present disclosure. Referring to FIG. 6, in the organic light-emitting display panel, the anode 11 and the cathode 12 are both taken as emergent light side electrodes, and after being formed on the light-emitting structure 13, one part of the light is emitted out via the anode 11, and the other part of the light is emitted out via the cathode 12. The material of both the anode 11 and the cathode 12 is silver or a silver-containing metallic material. In order to make both the anode 11 and the cathode 12 have good light transmittance, the thickness of the emergent light side electrode (including the anode 11 and the cathode 12) may be set thinner than 30 nm.

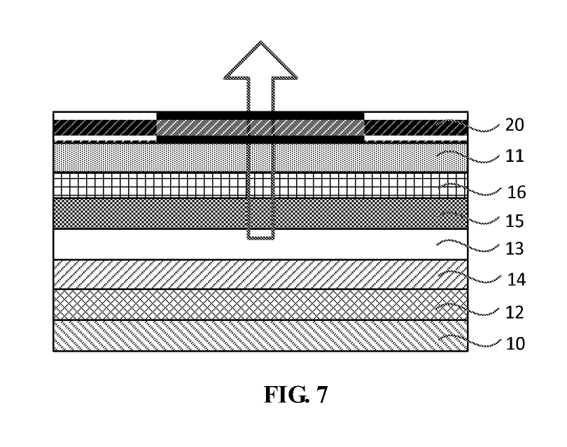

FIG. 7 is a structural representation of yet another organic light-emitting display panel according to one embodiment of the present disclosure. As shown in FIG. 7, the organic light-emitting display panel may further include an optical coupling layer 20. The optical coupling layer 20 is located on one side of the emergent light side electrode of the organic light-emitting display panel that is far away from the light-emitting structure 13. In FIG. 7, only the anode 11 is an emergent light side electrode, and the optical coupling layer 20 is located on one side of the anode 11 of the organic light-emitting display panel that is far away from the light-emitting structure 13.

Considering that the organic light-emitting display panel does not include an optical coupling layer 20, the process in which the light is emitted from the emergent light side electrode (the anode 11) into the air will essentially be a process in which the light is emitted from an optically denser medium into an optically thinner medium. The light tends to be reflected at the interface between the emergent light side electrode (the anode 11) and the air, and hence the light transmittance will be lowered. In the technical solutions of this application, the arrangement of the optical coupling layer 20 is essentially to change the refractive index of the contact surface between the emergent light side of the organic light-emitting display panel and the air so as to suppress the reflection of light, thereby improving the light transmittance.

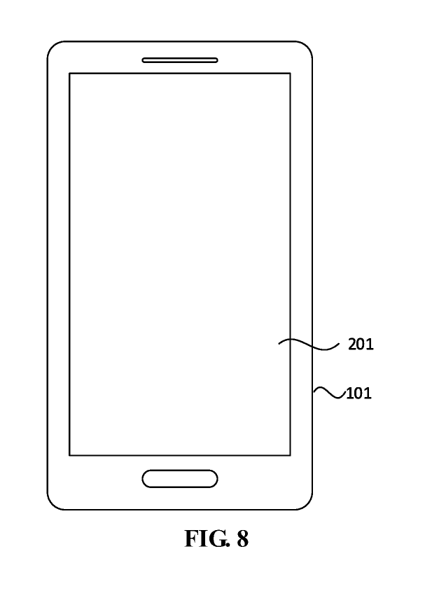

One embodiment of the present disclosure further provides an organic light-emitting display device. FIG. 8 is a structural representation of an organic light-emitting display device according to one embodiment of the present disclosure. Referring to FIG. 8, the organic light-emitting display device 101 includes any organic light-emitting display panel 201 according to the embodiments of the present disclosure. Specifically, the organic light-emitting display device 101 may be a mobile phone, a notebook computer, an intelligent wearable device and an information inquiry machine in a public hall.

With the organic light-emitting display device according to the embodiment of the present disclosure, the problem of low light-emitting efficiency of the existing inverted organic light-emitting display panel may be solved by multiplexing the first auxiliary functional structure located between the cathode and the light-emitting structure in its internal organic light-emitting display panel as a micro-cavity length adjusting structure, thereby increasing the light-emitting efficiency and the lightness of inverted organic light-emitting display panels and improving the performance of inverted organic light-emitting display panels.

It should be noted that the embodiments of the present disclosure and the technical principles used therein are described as above. It should be appreciated that the disclosure is not limited to the particular embodiments described herein, and any apparent alterations, modification and substitutions can be made without departing from the scope of protection of the disclosure. Accordingly, while the disclosure is described in detail through the above embodiments, the disclosure is not limited to the above embodiments and can further include other additional embodiments without departing from the concept of the disclosure.

What is claimed is:

1. An organic light-emitting display panel, comprising:
a substrate, a cathode, a first auxiliary functional structure, a light-emitting structure and an anode, wherein the substrate, the cathode, the first auxiliary functional structure, the light-emitting structure and the anode are successively laminated;
wherein the anode and the cathode are both made of silver or a silver-containing metallic material, and wherein a micro-cavity structure is formed between the cathode and the anode; and
wherein the first auxiliary functional structure comprises at least one of an electron injection layer, an electron transport layer, and a hole blocking layer; and
wherein the first auxiliary functional structure is multiplexed as a micro-cavity length adjusting structure.

2. The organic light-emitting display panel as claimed in claim 1, wherein
a thickness of the micro-cavity length adjusting structure is greater than 600 Å.

3. The organic light-emitting display panel as claimed in claim 2, wherein
the electron transport layer comprises an alkali metal, an alkaline earth metal and a rare earth metal.

4. The organic light-emitting display panel as claimed in claim 3, wherein
the electron transport layer further comprises lithium, cesium and ytterbium.

5. The organic light-emitting display panel as claimed in claim 3, wherein
a mass percent of the metal doped in the electron transport layer is in the range of 5% to 50%.

6. The organic light-emitting display panel as claimed in claim 1, further comprising a second auxiliary functional structure;
wherein the second auxiliary functional structure is located between the light-emitting structure and the anode; and
wherein the second auxiliary functional structure comprises at least one of an electron blocking layer, a hole transport layer and a hole injection layer.

7. The organic light-emitting display panel as claimed in claim 6,
wherein the hole transport layer is disposed inside the second auxiliary functional structure; and
wherein the hole transport layer is doped with a P-type semiconductor material, or a P-type semiconductor material layer is provided between the hole transport layer and the anode.

8. The organic light-emitting display panel as claimed in claim 7,
wherein the hole transport layer is doped with a P-type semiconductor material; and
wherein a mass percent of the P-type semiconductor material in the hole transport layer is greater than or equal to 1% and is less than or equal to 10%.

9. The organic light-emitting display panel as claimed in claim 8, wherein
a thickness of the hole transport layer is in the range of 50 Å to 300 Å.

10. The organic light-emitting display panel as claimed in claim 7, further comprising a P-type semiconductor material layer provided between the hole transport layer and the anode; wherein
the thickness of the P-type semiconductor material layer in the range of 50 Å to 100 Å.

11. The organic light-emitting display panel as claimed in claim 7, wherein
a lowest unoccupied molecular orbital energy level of the P-type semiconductor material is less than −5 eV.

12. The organic light-emitting display panel as claimed in claim 7, wherein
the anode and the cathode are both made of a silver-containing metallic material, and a mass percent of silver is greater than or equal to 10%.

13. The organic light-emitting display panel as claimed in claim 12, wherein
the anode and the cathode are both made of a silver-magnesium alloy or a silver-ytterbium alloy.

14. The organic light-emitting display panel as claimed in claim 12,
wherein at least one of the anode and the cathode is an emergent light side electrode of the organic light-emitting display panel; and wherein a thickness of the emergent light side electrode is less than 30 nm.

15. The organic light-emitting display panel as claimed in claim 14, further comprising an optical coupling layer located on one side of the emergent light side electrode of the organic light-emitting display panel that is facing away from the light-emitting structure.

16. An organic light-emitting display device, comprising an organic light-emitting display panel which comprises:
a substrate, a cathode, a first auxiliary functional structure, a light-emitting structure and an anode, wherein the substrate, the cathode, the first auxiliary functional structure, the light-emitting structure and the anode are successively laminated;
wherein the anode and the cathode are both made of silver or a silver-containing metallic material, and wherein a micro-cavity structure is formed between the cathode and the anode; and
wherein the first auxiliary functional structure comprises at least one of an electron injection layer, an electron transport layer, and a hole blocking layer; and
wherein the first auxiliary functional structure is multiplexed as a micro-cavity length adjusting structure.
